(19) United States
(12) Patent Application Publication
(10) Pub. No.: US 2025/0351466 A1
(43) Pub. Date: Nov. 13, 2025

(54) OXIDE SEMICONDUCTOR FERROELECTRIC FIELD EFFECT TRANSISTOR

(71) Applicant: Taiwan Semiconductor Manufacturing Company, Ltd., Hsin-Chu (TW)

(72) Inventors: Chun-Chieh Lu, Taipei City (TW); Yu-Chuan Shih, Hsinchu City (TW); Yu-Ming Lin, Hsinchu City (TW)

(21) Appl. No.: 19/279,468

(22) Filed: Jul. 24, 2025

Related U.S. Application Data
(63) Continuation of application No. 18/620,250, filed on Mar. 28, 2024.
(60) Provisional application No. 63/622,266, filed on Jan. 18, 2024.

(51) Int. Cl. H10D 30/69; H01L 23/532; H10D 30/01; H10D 64/68; H10D 99/00

(52) U.S. Cl. CPC H10D 30/701; H01L 23/53266; H10D 30/0415; H10D 64/691; H10D 99/00

(57) ABSTRACT

Oxide semiconductor ferroelectric field effect transistors (OS-FeFETs) and method of forming the same are provide. A device disclosed herein includes an electrode in a first dielectric layer, a ferroelectric layer over the electrode and the first dielectric layer, a high-k dielectric layer over the ferroelectric layer, an oxide semiconductor layer over the high-k dielectric layer, a second dielectric layer over the oxide semiconductor layer and the high-k dielectric layer, and a first contact feature and a second contact feature extending through the second dielectric layer to contact the oxide semiconductor layer.

### PRIORITY DATA

This application is a continuation application of U.S. patent application Ser. No. 18/620,250, filed Mar. 28, 2024, which claims priority to U.S. Provisional Patent Application Ser. No. 63/622,266, filed Jan. 18, 2024, each of which is incorporated herein by reference in its entirety.

### BACKGROUND

In the modern big-data era, artificial intelligence technology has been evolving quickly to use predictions and automation to optimize and solve complex tasks. A neural network is a branch of artificial intelligence technology where a deep learning model learns from a vast amount of data in order to make a reliable decision. Today, most computers employ von Neumann architecture where memory and a processing unit are separate. The performance of a von Neumann architecture computer is limited by the speed of accessing memory because the speed to access memory is a lot slower than the processing speed. The von Neumann architecture may not be ideal for implementation of neural networks because operation of neural networks requires movement of enormous amounts of data and doing so in the von Neumann architecture is not only slow but also consumes a large amount of energy. To overcome the von Neumann bottleneck and to reduce power consumption, a brain-inspired neuromorphic computing system that simulate operations of a human brain has undergone rapid development. A human brain has 100 billion neurons interconnected by a quadrillion synapses. Like a human brain, a neuromorphic computing system includes artificial neurons and artificial synapses.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to various aspects of the present disclosure.

FIGS. 2-18 illustrates fragmentary cross-sectional views of a work-in-progress (WIP) structure undergoing various steps of the method in FIG. 1, according to various aspects of the present disclosure.

FIG. 19 illustrates an electric field across interface layers of different dielectric materials between a ferroelectric layer and an oxide semiconductor layer.

FIG. 20 illustrates how interface trap densities change over potentiation-depression cycles.

FIG. 21 illustrates an example deployment of the semiconductor device of the present disclosure in a back-end-of-line (BEOL) structure, according to various aspects of the present disclosure.

FIG. 22 illustrates a schematic top view of an array that includes the semiconductor device of the present disclosure, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

In a human brain, synapses transmit and integrate processed signals between neurons. In neural science, synaptic plasticity refers to the ability of neurons to modify the strength of their connections through synapses. The connection strength is described by synaptic weight or synaptic strength. The continuous change in ferroelectric polarization due to external field modulation is found to be similar to the continuous change in the weights of connections between biological synapses. In an ideal case, a ferroelectric field effect transistor (FeFET) exhibits perfectly symmetrical potentiation or depression synaptic behaviors and provides linear weight update. In reality, the synaptic characteristics of an FeFET may degrade over time due to presence of interface traps. Interface traps may cause threshold voltage shift in a direction opposite to the direction the threshold voltage shifts due to polarization.

The present disclosure provides an oxide semiconductor field effect transistor (OS-FeFET) device that has symmetrical potentiation/depression synaptic behaviors and a method for fabricating the same The OS-FET device is compatible with existing complementary metal-oxide-semiconductor (CMOS) technology and may be fabricated in the front-end-of-line (FEOL) structure of the back-end-of-line (BEOL) structure. In an example process, an electrode is formed in a first dielectric layer. A ferroelectric layer is deposited over a planar surface of the first dielectric layer and the electrode. A high-k dielectric layer is deposited over the ferroelectric layer. An oxide semiconductor layer is then deposited over the high-k dielectric layer. The high-k dielectric layer is configured to modify the Fowler-Nordheim (FN) tunneling behavior between the ferroelectric layer and the oxide semiconductor layer. After the oxide semiconductor layer is patterned to expose a portion of the high-k dielectric layer, a second dielectric layer is deposited over the patterned oxide semiconductor layer and the high-k dielectric layer. A source electrode and a drain electrode are then formed in the second dielectric layer to contact the oxide semiconductor layer. The high-k dielectric layer suppresses interface trap generation and may provide a symmetrical potentiation/depression synaptic characteristics.

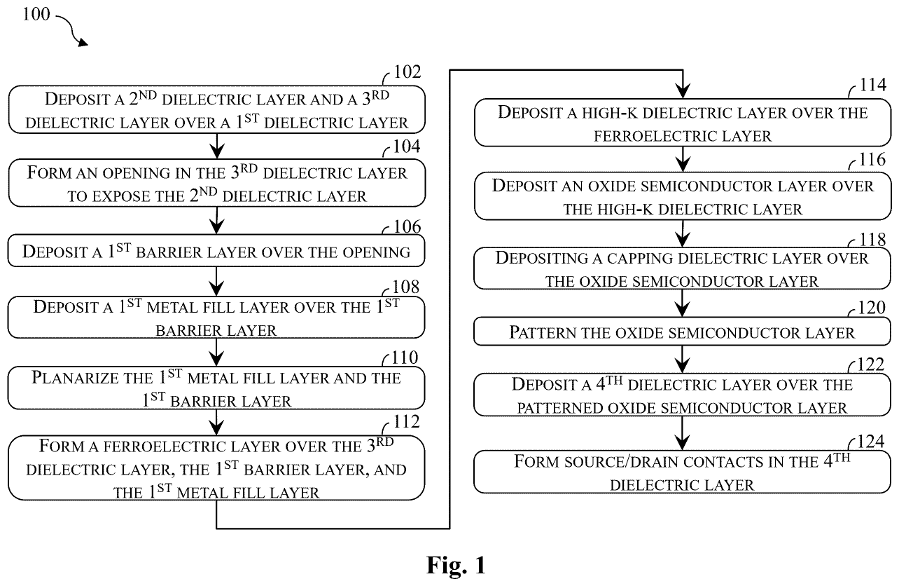

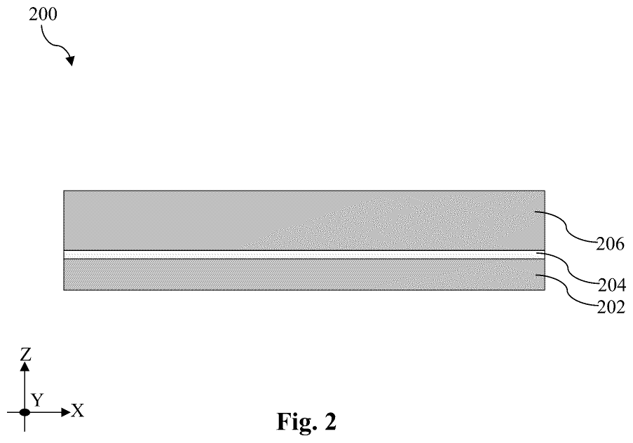

The various aspects of the present disclosure will now be described in more detail with reference to the figures. In that regard, FIG. 1 is a flowchart illustrating method 100 of forming a semiconductor device. Method 100 is merely an example and are not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIG. 2-18, which illustrate fragmentary cross-sectional views of a work-in-progress (WIP) structure undergoing various operations of method 100. For avoidance of doubts, the X, Y and Z directions in FIGS. 2-18 are perpendicular to one another. Throughout the present disclosure, unless expressly otherwise described, like reference numerals denote like features.

Referring to FIGS. 1 and 2, method 100 includes a block 102 where a second dielectric layer 204 and a third dielectric layer 206 is deposited over a first dielectric layer 202. The first dielectric layer 202 may include silicon oxide, silicon nitride, silicon oxynitride, fluorine-doped silicate glass (FSG), a low-k dielectric, combinations thereof, and/or other suitable materials. In one embodiment, the first dielectric layer 202 may include silicon oxide. When the resulting semiconductor device formed using method 100 is disposed near or at the front-end-of-line (FEOL) level or the middle-end-of-line (MEOL), the first dielectric layer 202 may be an interlayer dielectric (ILD) layer that is disposed around or adjacent a source/drain contact of a transistor formed on a semiconductor substrate. When the resulting semiconductor device formed using method 100 is disposed in an interconnect structure at the back-end-of-line (BEOL) level, the first dielectric layer 202 may be an intermetal dielectric (IMD) layer that surrounds and insulates metal lines or contact vias. The second dielectric layer 204 is an etch stop layer (ESL) that etches at a slow rate than the first dielectric layer 202. In some embodiments, the second dielectric layer 204 may include aluminum nitride, aluminum oxide, boron nitride, silicon oxynitride, silicon oxycarbonitride, or a combination thereof. In one embodiment, the second dielectric layer 204 includes aluminum oxide. In some implementations, the second dielectric layer 204 may be deposited over the first dielectric layer 202 using atomic layer deposition (ALD), chemical vapor deposition (CVD), or physical vapor deposition (PVD). The third dielectric layer 206 may share the same composition with the first dielectric layer 202. In some embodiments, the third dielectric layer 206 may include silicon oxide, silicon nitride, silicon oxynitride, fluorine-doped silicate glass (FSG), a low-k dielectric, combinations thereof, and/or other suitable materials. In one embodiment, the third dielectric layer 206 may include silicon oxide. The third dielectric layer 206 may be an IMD layer in an interconnect structure at the BEOL level. A dielectric constant of the second dielectric layer 204 is greater than a dielectric contact of the first dielectric layer 202 or the third dielectric layer 206. To reduce parasitic capacitance, a thickness of the second dielectric layer 204 is smaller than a thickness of the first dielectric layer 202 or the third dielectric layer 206.

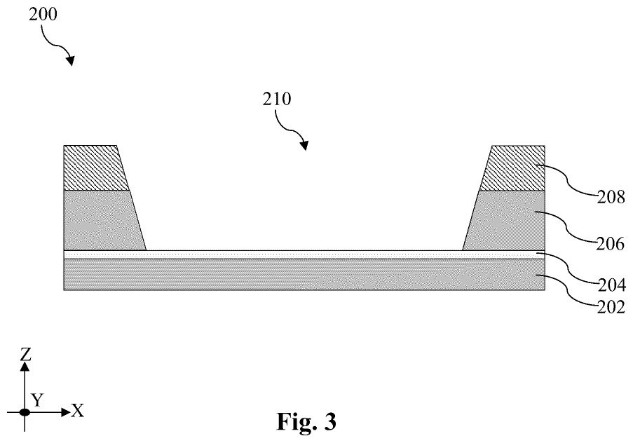

Referring to FIGS. 1 and 3, method 100 includes a block 104 where an opening 210 is formed in the third dielectric layer 206 to expose the second dielectric layer 204. In an example process, a photoresist layer 208 is deposited over the third dielectric layer 206 using spin-on coating. After the deposition of the photoresist layer 208, photolithography processes and etch processes are performed to pattern the photoresist layer 208. The patterned photoresist layer 208 is then used as an etch mask in etching the third dielectric layer 206 to form the opening 210. At block 104, the third dielectric layer 206 may be anisotropically etched using a reactive-ion-etching (RIE) process that uses oxygen, hydrogen, a fluorine-containing gas (e.g., CF₄, NF₃, SF₆, CH₂F₂, CHF₃, and/or C₂F₆), a hydrocarbon (e.g., methane), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As shown in FIG. 3, sidewalls of the opening 210 is defined in the third dielectric layer 206 and a top surface of the second dielectric layer 204 is exposed in the opening 210. After the formation of the opening 210, the patterned photoresist layer 208 is removed by stripping, ashing or selective etching. Because the opening 210 is going to accommodate a gate electrode, it may also be referred to as a gate opening 210.

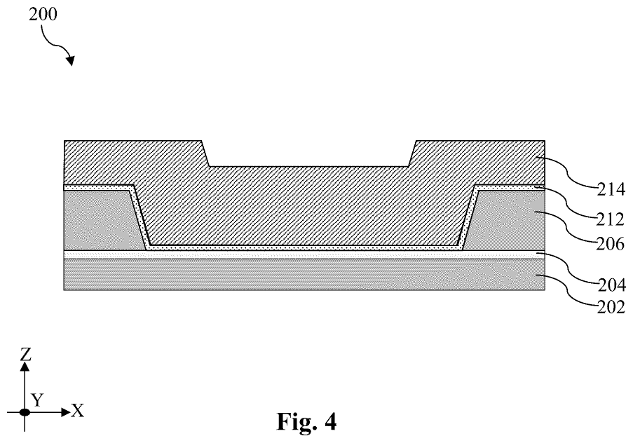

Referring to FIGS. 1 and 4, method 100 includes a block 106 where a first barrier layer 212 is deposited over the opening 210. In some embodiments, the first barrier layer 212 includes metal nitride, such as titanium nitride (TiN) or tantalum nitride (TaN). In one embodiment, the first barrier layer 212 includes titanium nitride (TiN). In some implementations, the first barrier layer 212 is deposited over the WIP structure 200, including the opening 210, by PVD or metalorganic CVD (MOCVD).

Referring to FIGS. 1 and 4, method 100 includes a block 108 where a first metal fill layer 214 is deposited over the first barrier layer 212. In order for the resulting semiconductor device to function satisfactorily, the first metal fill layer 214 possess suitable work function to interface the to-be-formed ferroelectric layer. Additionally, it is desirable that the first metal fill layer 214 is less prone to electromigration to increase an endurance of the resulting semiconductor device. In some embodiments, the first metal fill layer 214 may include tungsten (W), ruthenium (Ru), or molybdenum (Mo). It is noted that the first metal fill layer 214 may be formed of a metal different from the metal of the metal lines or vias in an interconnect structure. For example, metal lines and vias in an interconnect structure may be formed of copper (Cu). The first metal fill layer 214 may be deposited over the first barrier layer 212 using PVD, CVD, or a combination thereof.

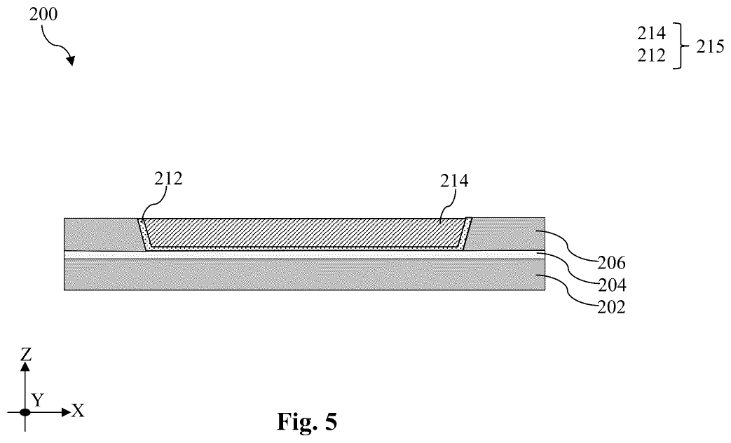

Referring to FIGS. 1 and 5, method 100 includes a block 110 where the first metal fill layer 214 and the first barrier layer 212 are planarized. As shown in FIG. 4, after deposition of the first metal fill layer 214, a top surface of the first metal fill layer 214 tracks the profile of the opening 210 and is not flat. At block, a planarization process, such as a chemical mechanical polishing (CMP) process, is performed to remove excess of the first metal fill layer 214 and the first barrier layer 212 to provide a planar top surface. As shown in FIG. 5, after the planarization process, top surfaces of the third dielectric layer 206, the first barrier layer 212, and the first metal fill layer 214 are exposed. After the planarization, the first barrier layer 212 and the first metal fill layer 214 may be referred collectively as an electrode 215 or a gate electrode 215.

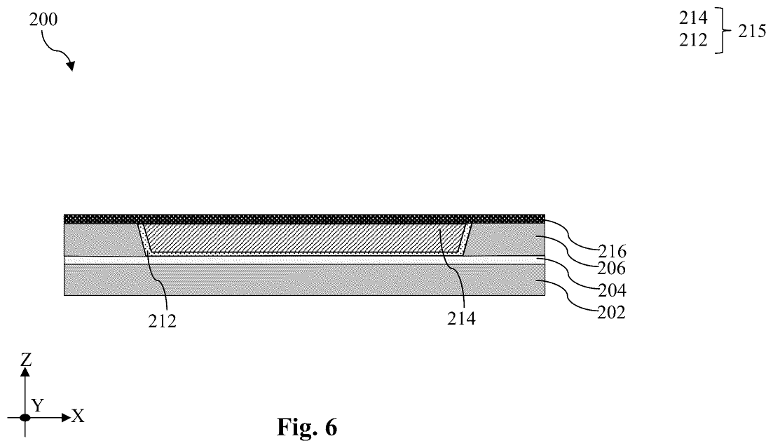

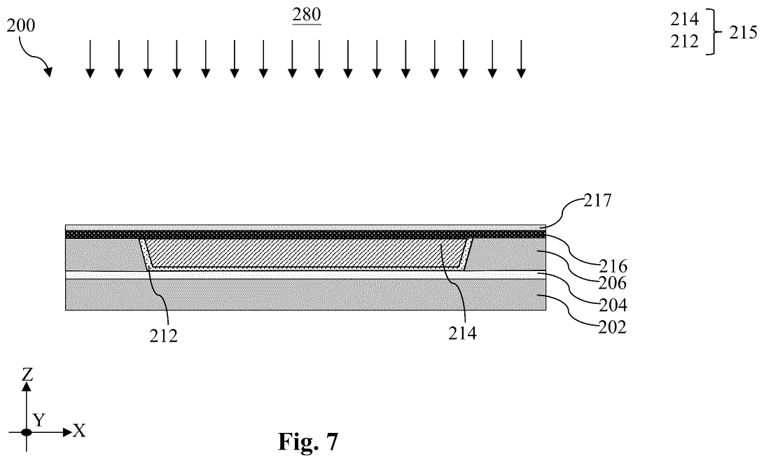

Referring to FIGS. 1, 6 and 7, method 100 includes a block 112 where a ferroelectric layer 216 is formed over the third dielectric layer 206, the first barrier layer 212 and the first metal fill layer 214. The ferroelectric layer 216 is a hafnium-oxide-based ferroelectric layer because a hafnium-oxide-based ferroelectric layer can be formed at lower temperature and is more compatible with existing complementary metal oxide semiconductor (CMOS) fabrication processes. In some embodiments, the ferroelectric layer 216 includes hafnium zirconium oxide (HfZrO), hafnium aluminum oxide (HfAlO), hafnium lanthanum oxide (HfLaO), hafnium cerium oxide (HfCeO), hafnium gadolinium oxide (HfGdO), hafnium silicate (HfSiO), or hafnium oxide doped with other metal or semiconductor. In one embodiment, the ferroelectric layer 216 includes hafnium zirconium having a zirconium to hafnium molar ratio between about 0.66 (i.e., Zr: 40%, Hf: 60%) and 4 (i.e., Zr: 80%, Hf: 20%). In order for the ferroelectric layer 216 to exhibit ferroelectricity, the ferroelectric layer 216 is deposited in a way such that includes an orthorhombic crystalline phase. In some embodiments represented in FIG. 6, the ferroelectric layer 216 is deposited using PVD, ALD, plasma-enhanced ALD (PEALD), CVD, plasma-enhanced CVD (PECVD), or pulsed laser deposition. To prevent damages done to existing structures, such as FEOL structures, the deposition of the ferroelectric layer 216 is performed at a temperature between about 200° C. and about 350° C. As shown in FIG. 6, the ferroelectric layer 216 is deposited directly on the top surfaces of the third dielectric layer 206, the first barrier layer 212, and the first metal fill layer 214. Reference is now made to FIG. 7. After the deposition of the ferroelectric layer 216 over the WIP structure 200, a cap layer 217 is deposited over the ferroelectric layer 216. In some embodiments, the cap layer 217 includes titanium nitride (TiN) and is deposited using PVD or MOCVD. The cap layer 217 acts as a stressor to promote formation of the ferroelectric orthorhombic phase in the ferroelectric layer 216. After the deposition of the cap layer 217, an anneal process 280 is performed to the WIP structure 200. To prevent damages done to existing structures, such as FEOL structures, the anneal process 280 includes an anneal temperature between about 300° C. and about 450° C., such as between about 350° C. and about 400° C. After performance of the anneal process 280, the cap layer 217 may be selectively removed using a wet etch process or a dry etch process. An example wet etch process may include use of ammonium hydroxide, hydrogen peroxide, or a combination thereof. An example dry etch process may include use of plasma of hydrogen chloride (HCl), chlorine (Cl₂), hydrogen (H₂), an inert gas (such as helium (He) or argon (Ar)), or a combination thereof. In some embodiments, the ferroelectric layer 216 has a thickness between about 2 nm and about 20 nm.

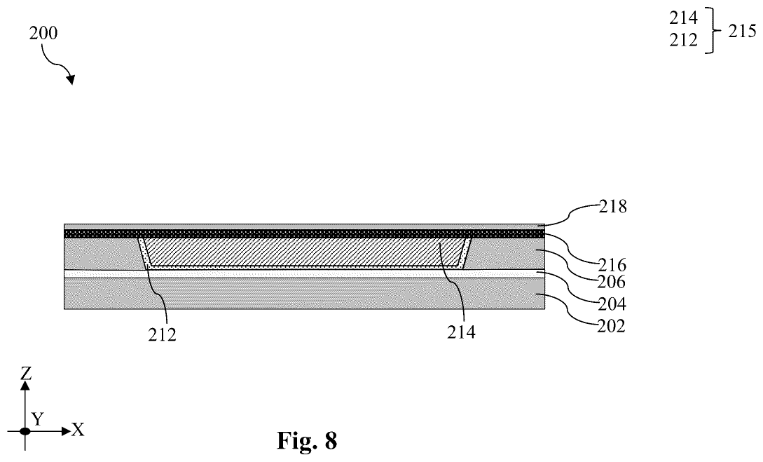

Referring to FIGS. 1 and 8, method 100 includes a block 114 where a high-k dielectric layer 218 is deposited over the ferroelectric layer 216. The high-k dielectric layer 218 includes metal oxide with metal compositions less miscible with the hafnium-based ferroelectric layer 216. When the high-k dielectric layer 218 includes metal oxide that is readily miscible with the ferroelectric layer 216, such as hafnium oxide or zirconium oxide, the deposition of the high-k dielectric layer 218 would effectively increase the thickness of the ferroelectric layer 216 or change the dopant molar ratios in the ferroelectric layer 216. In some embodiments, the high-k dielectric layer 218 includes aluminum oxide (Al₂O₃), titanium oxide (TiO₂), niobium oxide (NbO), or lanthanum oxide (La₂O₃). In one embodiment, the high-k dielectric layer 218 includes titanium oxide (TiO₂). The high-k dielectric layer 218 may be deposited using PVD, ALD, PEALD, CVD, or PECVD. As will be described further below, an oxide semiconductor layer is going to be deposited over the high-k dielectric layer 218. Because the ferroelectric layer 216 interfaces the oxide semiconductor layer by way of the high-k dielectric layer 218, the high-k dielectric layer 218 functions as an interface layer and may be referred to as such.

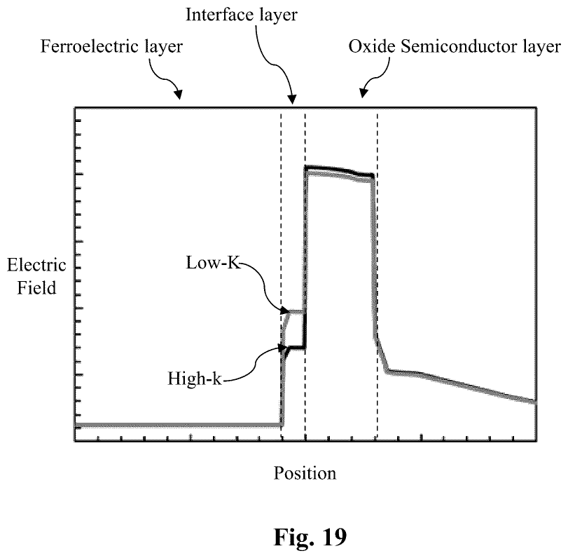

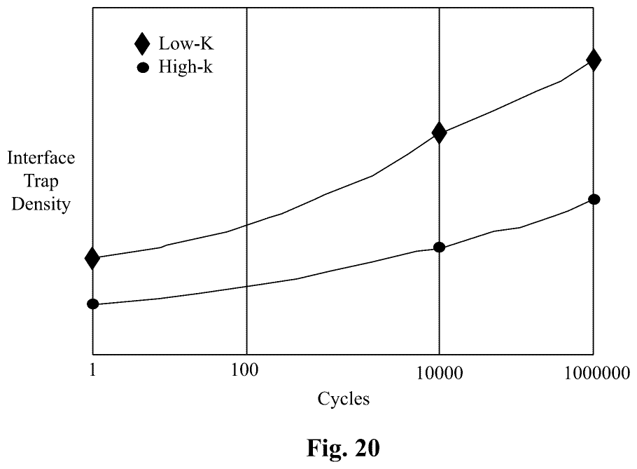

While a high-k dielectric layer is customarily used to refer to a dielectric layer having a dielectric constant greater than that of silicon oxide (˜3.9), a dielectric constant of the high-k dielectric constant of the high-k dielectric layer 218 in the present disclosure is greater than 9. The high dielectric constant of the high-k dielectric layer 218 increase endurance and reliability of the ferroelectric layer 216. It has been observed that a hafnium-based ferroelectric layer may fatigue after potentiation-depression cycles. Such fatigue may be associated with formation of traps at interfaces of the ferroelectric layer with other layers. According to observation and research, the formation of traps may be linked to Fowler-Nordheim (FN) tunneling driven by electric field strength. Reference is now made to FIGS. 19, which schematically illustrates strength of an electric field in an interface layer between a ferroelectric layer and an semiconductor layer when the interface layer is formed of different dielectric materials. Compared to an interface layer formed a low-k dielectric layer (such as one having a dielectric constant about 4), a high-k dielectric layer (such as the high-k dielectric layer 218 having a dielectric constant greater than 9) helps reduce the electric field across in the interface layer. Such reduction in electric field strength can reduce the FN tunnel effect at the interface. Reference is further made to FIG. 20, which schematically illustrates change of interface trap densities over potentiation-depression cycles. Compared to an interface layer formed a low-k dielectric layer (such as one having a dielectric constant about 4), a high-k dielectric layer (such as the high-k dielectric layer 218 having a dielectric constant greater than 9) keeps the interface density low through potentiation-depression cycles. The reduced FN tunnel effect is also conducive symmetrical potentiation and depression characteristics, which is desirable for neuromorphic computing applications.

While greater dielectric constant of the high-k dielectric layer 218 provides benefits, it may also increase a threshold voltage of the resulting semiconductor device. To compensate for the greater dielectric constant, a thickness of the high-k dielectric layer 218 is smaller than that of the ferroelectric layer 216 or an oxide semiconductor layer 220 to be deposited at block 116. In some implementations, the high-k dielectric layer 218 has a thickness between about 0.1 nm and about 2 nm.

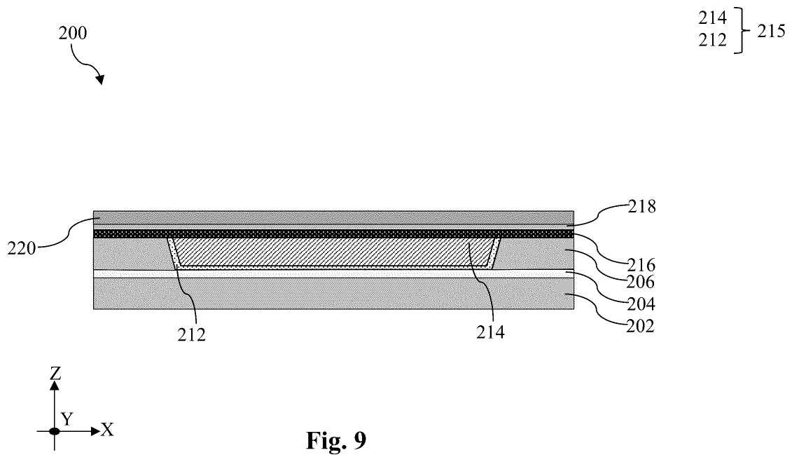

Referring to FIGS. 1 and 9, method 100 includes a block 116 where an oxide semiconductor layer 220 is deposited over the high-k dielectric layer 218. In some embodiments, the oxide semiconductor layer 220 may include zinc oxide, indium tungsten oxide, indium gallium zinc oxide, indium zinc oxide, or indium tin oxide. In some embodiments, the oxide semiconductor layer 220 may be deposited over the high-k dielectric layer using PVD, ALD, PEALD, CVD, or PECVD. In some implementations, the oxide semiconductor layer 220 includes a thickness between about 2 nm and about 20 nm.

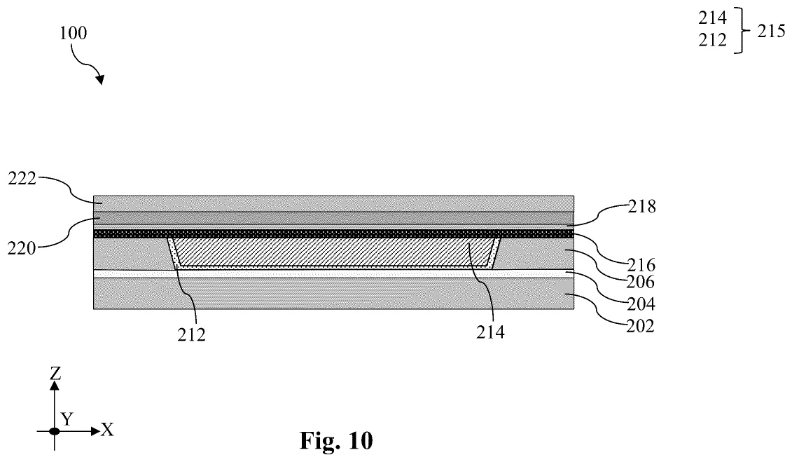

Referring to FIGS. 1 and 10, method 100 includes a block 118 where a capping dielectric layer 222 is deposited over the oxide semiconductor layer 220. The capping dielectric layer 222 protects the oxide semiconductor layer 220 in a subsequent patterning process. In some embodiments, the capping dielectric layer 222 includes silicon oxide and may be deposited using CVD.

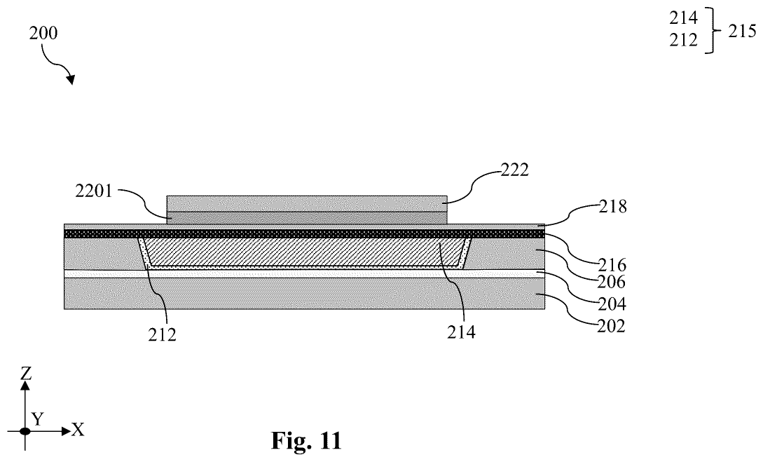

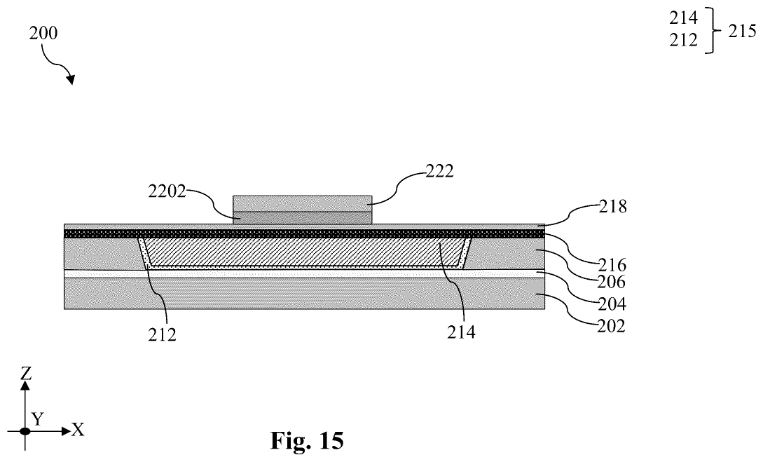

Referring to FIGS. 1, 11 and 15, method 100 includes a block 120 where the oxide semiconductor layer 220 is patterned. To pattern the oxide semiconductor layer 220, a photoresist layer may be blanketly deposited over the WIP structure 200, including over the capping dielectric layer 222. The photoresist layer may be a single layer or a multi-layer, such as a tri-layer. The photoresist layer is then exposed to radiation going through or reflected from a mask, baked in a post-bake process, and developed in a developer solution to form a patterned photoresist mask. The oxide semiconductor layer 220 is then etched using the patterned photoresist mask as an etch mask. The etch process at block 120 may be a reactive-ion-etching (RIE) process that uses oxygen, hydrogen, a fluorine-containing gas (e.g., CF₄, NF₃, SF₆, CH₂F₂, CHF₃, and/or C₂F₆), a hydrocarbon (e.g., methane), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some embodiments represented in FIGS. 11 and 15, the etching to pattern the oxide semiconductor layer 220 is time-controlled to stop at the high-k dielectric layer 218 or is made to etch the high-k dielectric layer 218 at a slower rate. In some embodiments, the remaining capping dielectric layer 222 is selectively removed. In some alternative embodiments, the remaining capping dielectric 222 is not removed.

Method 100 of the present application is suitable to form semiconductor devices of different structural configurations. FIGS. 11-14 illustrate process steps leading to a first configuration where source/drain contacts engage a top surface of the oxide semiconductor layer 220. FIGS. 15-18 illustrate process steps leading to a second configuration where source/drain contacts engage sidewalls of the oxide semiconductor layer 220. Operations at block 120 may pattern the oxide semiconductor layer 220 into a first oxide semiconductor layer 2201 shown in FIG. 11 or a second oxide semiconductor layer 2202 shown in FIG. 15. Because the source/drain contacts are disposed over the first oxide semiconductor layer 2201, a length of the first oxide semiconductor layer 2201 is greater than a length of the second oxide semiconductor layer 2202.

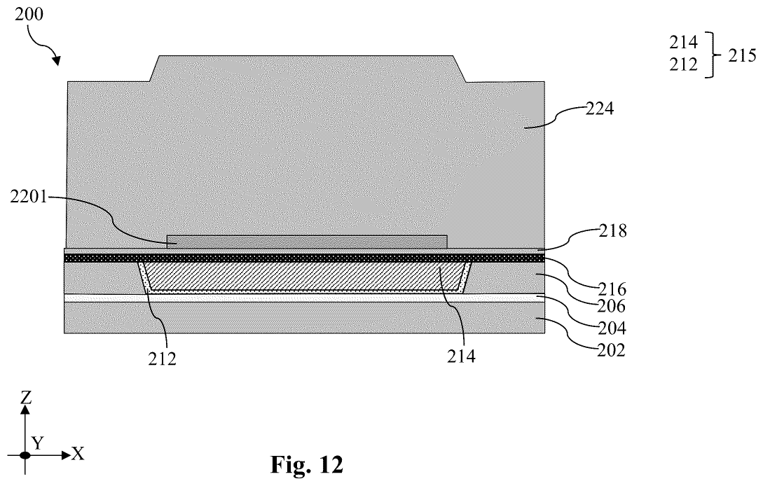

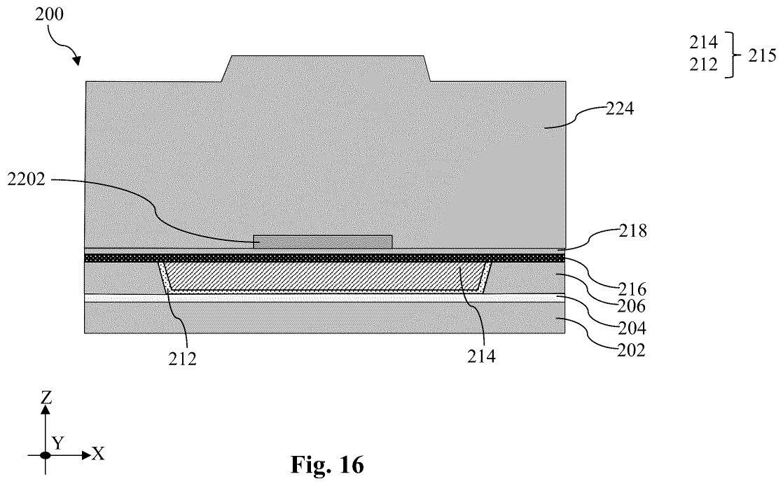

Referring to FIGS. 1, 12 and 16, method 100 includes a block 122 where a fourth dielectric layer 224 is deposited over the patterned oxide semiconductor layer. The fourth dielectric layer 224 may share the same composition with the first dielectric layer 202. In some embodiments, the fourth dielectric layer 224 may include silicon oxide, silicon nitride, silicon oxynitride, fluorine-doped silicate glass (FSG), a low-k dielectric, combinations thereof, and/or other suitable materials. In one embodiment, the fourth dielectric layer 224 may include silicon oxide. The fourth dielectric layer 224 may be an IMD layer in an interconnect structure at the BEOL level. In some embodiments, the capping dielectric layer 222 and the fourth dielectric layer 224 may be formed of the same material. This explains that removal of the leftover capping dielectric layer 222 is optional. FIG. 12 illustrates that the fourth dielectric layer 224 is deposited over the first oxide semiconductor layer 2201 and the high-k dielectric layer 218. FIG. 16 illustrates that the fourth dielectric layer 224 is deposited over the second oxide semiconductor layer 2202 and the high-k dielectric layer 218.

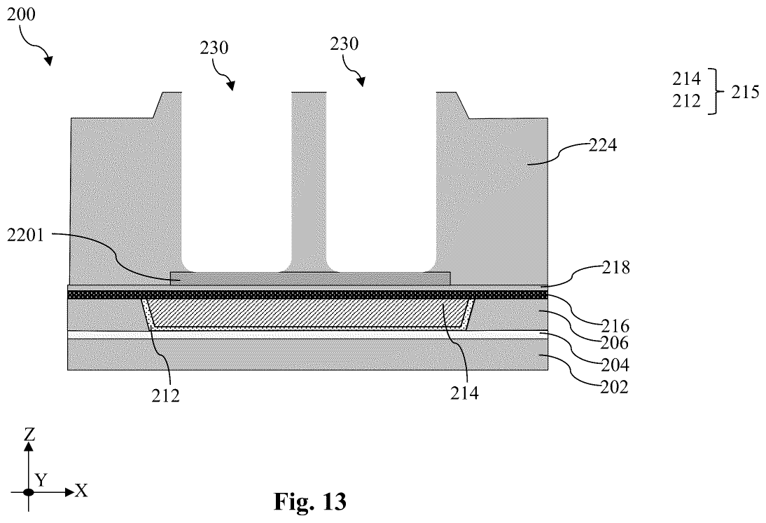

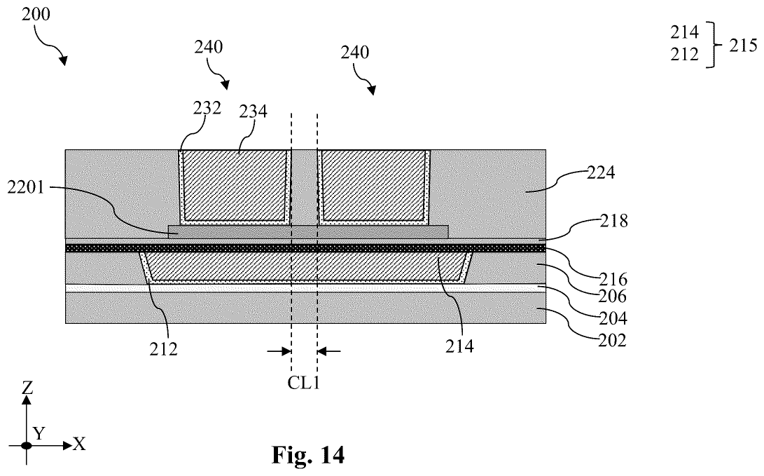

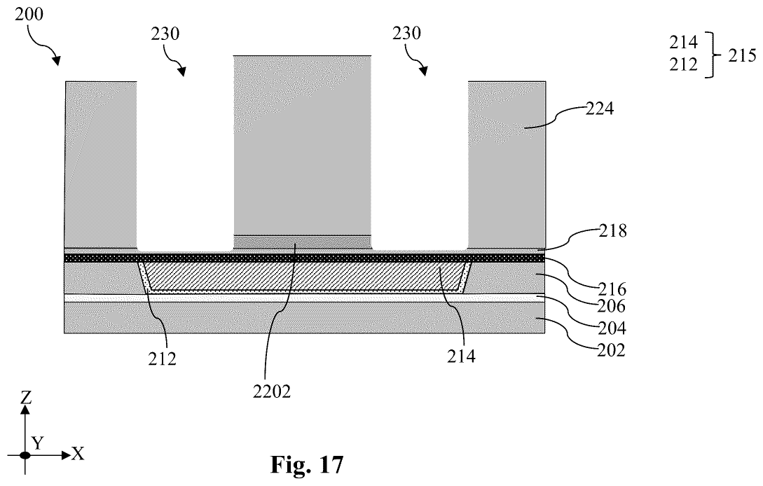

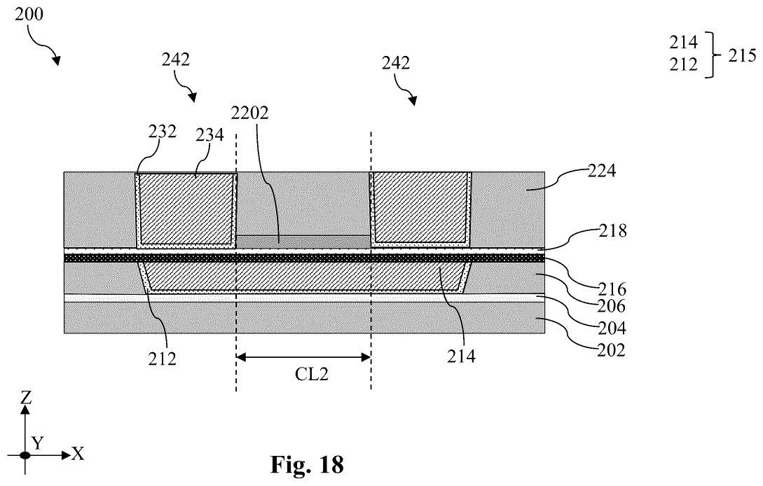

Referring to FIGS. 1, 13, 14, 17, and 18, method 100 includes a block 124 where source/drain contacts are formed in the fourth dielectric layer 224. Operations at block 124 include formation of contact openings 230 (shown in FIGS. 13 and 17), deposition of a second barrier layer 232 over the contact openings 230 (shown in FIGS. 14 and 18), and deposition of a second metal fill layer 234 over the second barrier layer 232 (not explicitly shown), and planarization of the second barrier layer 232 and the second metal fill layer 234 (shown in FIGS. 14 and 18).

Reference is first made to FIGS. 13 and 17. Block 124 form the contact openings 230 through the fourth dielectric layer 224. In embodiments represented in FIG. 13, the contact openings 230 are disposed directly over the first oxide semiconductor layer 2201 to expose portions of the top surface of the first oxide semiconductor layer 2201. In other words, in the first configuration, vertical projection areas of the contact openings 230 overlap with a vertical projection area of the first oxide semiconductor layer 2201. In embodiments represented in FIG. 17, the contact openings 230 are disposed directly over the high-k dielectric layer 218 to expose sidewalls of the second oxide semiconductor layer 2202. In the second configuration, vertical projection areas of the contact openings 230 overlap with a vertical projection area of the electrode 215 to expose sidewalls of the second oxide semiconductor layer 2202. In an example process, a photoresist layer is deposited over the fourth dielectric layer 224 using spin-on coating. After the deposition of the photoresist layer, photolithography processes and etch processes are performed to pattern the photoresist layer. The patterned photoresist layer is then used as an etch mask in etching the fourth dielectric layer 224 to form the contact openings 230. At block 124, the fourth dielectric layer 224 may be anisotropically etched using a reactive-ion-etching (RIE) process that uses oxygen, hydrogen, a fluorine-containing gas (e.g., CF₄, NF₃, SF₆, CH₂F₂, CHF₃, and/or C₂F₆), a hydrocarbon (e.g., methane), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. After the formation of the contact openings 230, the patterned photoresist layer is removed by stripping, ashing or selective etching. Because the contact openings 230 are going to accommodate source/drain contact, they may also be referred to as source/drain contact openings 230. When the second configuration is desired, the contact openings 230 are controlled to not to etch through the high-k dielectric layer 218. In the embodiments illustrated in FIG. 17, the contact openings 230 partially extend into the high-k dielectric layer 218 but do not extend completely through the high-k dielectric layer 218.

Reference is then made to FIGS. 14 and 18. After the contact openings 230 are formed, the second barrier layer 232 may be deposited over the WIP structure 200 using PVD or MOCVD. In some embodiments, the second barrier layer 232 includes metal nitride, such as titanium nitride (TiN) or tantalum nitride (TaN). In one embodiment, the second barrier layer 232 includes titanium nitride (TiN). When the first configuration is desired, the deposited second barrier layer 232 is deposited directly on the top surface of the first oxide semiconductor layer 2201, as shown in FIG. 14. When the second configuration is desired, the deposited second barrier layer 232 is deposited directly on the top surface of the high-k dielectric layer 218 and is contact with sidewalls of the second oxide semiconductor layer 2202, as shown in FIG. 18.

Reference is still made to FIGS. 14 and 18. After the second barrier layer 232 is deposited, the second metal fill layer 234 is deposited over the second barrier layer 232. In order for the resulting semiconductor device to function satisfactorily, the second metal fill layer 234 possess suitable work function to interface the first oxide semiconductor layer 2201 or the second oxide semiconductor layer 2202. Additionally, it is desirable that the second metal fill layer 234 is less prone to electromigration to increase an endurance of the resulting semiconductor device. In some embodiments, the second metal fill layer 234 may include tungsten (W), ruthenium (Ru), or molybdenum (Mo). It is noted that the second metal fill layer 234 may be formed of a metal different from the metal of the metal lines or vias in an interconnect structure. For example, metal lines and vias in an interconnect structure may be formed of copper (Cu). The second metal fill layer 234 may be deposited over the second barrier layer 232 using PVD, CVD, or a combination thereof. After deposition of the second metal fill layer 234, the second barrier layer 232 and the second metal fill layer 234 are subject to a planarization process, such as a chemical mechanical polishing (CMP) process. The planarization process removes excess of the second metal fill layer 234 and the second barrier layer 232 to provide a planar top surface. As shown in FIGS. 14 and 18, after the planarization process, top surfaces of the fourth dielectric layer 224, the second barrier layer 232, and the second metal fill layer 234 are exposed in the planar to surface. After the planarization process, the second barrier layer 232 and the second metal fill layer 234 in FIG. 14 may be collectively referred to as a first source/drain contact 240 and the second barrier layer 232 and the second metal fill layer 234 in FIG. 18 may be collectively referred to as a second source/drain contact 242.

Upon completion of operations at block 124, a semiconductor device 200 is substantially formed. FIG. 14 illustrates the semiconductor device 200 having a first configuration. The semiconductor device 200 in FIG. 14 includes a gate electrode 215 disposed in the third dielectric layer 206. The ferroelectric layer 216 is disposed directly on top surfaces of the gate electrode 215 and the third dielectric layer 206. The ferroelectric layer 216 is hafnium-oxide-based and includes at least hafnium and oxygen. The high-k dielectric layer 218 is disposed directly on the ferroelectric layer 216 and functions to increase endurance of the semiconductor device 200. The first oxide semiconductor layer 2201 is disposed directly on the high-k dielectric layer 218. The fourth dielectric layer 224 is disposed over the first oxide semiconductor layer 2201. The first source/drain contacts 240 extend through the fourth dielectric layer 224 to contact the top surface of the first oxide semiconductor layer 2201. The polarizations with different polarities stored in the ferroelectric layer 216 may affect a threshold voltage of the semiconductor device 200, and can be non-destructively read out by sensing a channel resistance in the first oxide semiconductor layer 2201 between the first source/drain contacts 240. The semiconductor device 200 in FIG. 14 has a first channel length CL1 between the two first source/drain contacts 240. The semiconductor device 200 may be referred to as a ferroelectric field effect transistor (FeFET). Because the channel of the FeFET 200 is formed of an oxide semiconductor (OS) material, the FeFET 200 is an OS-FeFET.

FIG. 18 illustrates the semiconductor device 200 having a second configuration. The semiconductor device 200 in FIG. 18 includes a gate electrode 215 disposed in the third dielectric layer 206. The ferroelectric layer 216 is disposed directly on top surfaces of the gate electrode 215 and the third dielectric layer 206. The ferroelectric layer 216 is hafnium-oxide-based and includes at least hafnium and oxygen. The high-k dielectric layer 218 is disposed directly on the ferroelectric layer 216 and functions to increase endurance of the semiconductor device 200. The second oxide semiconductor layer 2202 is disposed directly on the high-k dielectric layer 218. The fourth dielectric layer 224 is disposed over the second oxide semiconductor layer 2202 and the high-k dielectric layer 218. The second source/drain contacts 242 extend through the fourth dielectric layer 224 to contact the top surface of the high-k dielectric layer 218 and sidewalls of the second oxide semiconductor layer 2202. As shown in FIG. 18, in the second configuration, no part of the second oxide semiconductor layer 2202 extends between the second source/drain contacts 242 and the high-k dielectric layer 218. The polarizations with different polarities stored in the ferroelectric layer 216 may affect a threshold voltage of the semiconductor device 200, and can be non-destructively read out by sensing a channel resistance in the second oxide semiconductor layer 2202 sandwiched between the second source/drain contacts 242. The semiconductor device 200 in FIG. 18 has a second channel length CL2 between the two second source/drain contacts 242. The semiconductor device 200 in FIG. 18 is also an OS-FeFET.

Semiconductor devices 200, whether having the first configuration shown in FIG. 14 or the second configuration shown in FIG. 18, may be suitable for various neuromorphic computing applications, such as in a computer-in-memory (CIM) structure, a processing-in-memory (PIM) structure, a processing-using-memory (CUM) structure, a near-memory-computing (NMC) structure, a near-data-processing (NDP) structure, an in-storage processing (ISP) structure, a graphics processing unit (GPU) accelerator, or a tensor processing unit (TCU) accelerator.

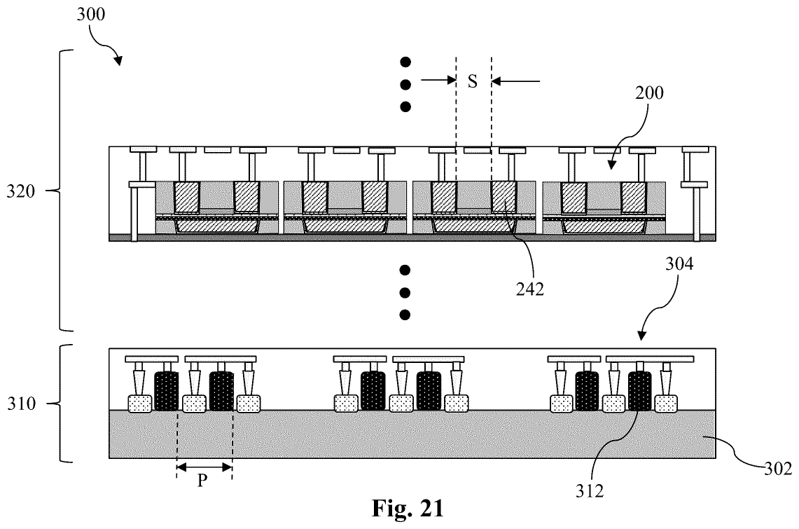

FIG. 21 illustrates an example integration of OS-FeFETs 200 in an integrated circuit (IC) die 300. As shown in FIG. 21, the IC die 300 includes a device substrate 310 and an interconnect structure 320 disposed over the device substrate 310. The device substrate 310 is fabricated at front-end-of-line (FEOL) and may be considered an FEOL structure. The interconnect structure 320 at back-end-of-line (BEOL) and may be considered an BEOL structure. The device substrate 310 may include a semiconductor substrate 302 and transistors 304 on the semiconductor substrate 302. The semiconductor substrate 302 may be a silicon (Si) substrate. In some other embodiments, the semiconductor substrate 302 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The semiconductor substrate 302 may also include an insulating layer, such as a silicon oxide layer, to have a silicon-on-insulator (SOI) structure.

Each of the transistors 304 may be a multi-gate device. Here, a multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. Because its gate structure surrounds the channel regions, GAA transistor may also be referred to as a surrounding gate transistor (SGT) or a multi-bridge-channel (MBC) transistor. The channel region of a GAA transistor may take form of nanowires, nanosheets, or other nanostructures and for that reasons, a GAA transistor may also be referred to as a nanowire transistor or a nanosheet transistor. As shown in FIG. 21, each of the transistors 304 includes a gate structure 312. In some embodiments, the gate structures 312 of the transistors 304 in the device substrate 310 extend lengthwise along the same direction and are characterized by a gate pitch P. In some instances, the gate pitch P is between about 50 nm and about 70 nm.

The interconnect structure 320 shown in FIG. 21 may include between about 8 and about 20 metallization layers, each of which includes contact vias and conductive lines embedded in an intermetal dielectric (IMD) layer. The interconnect structure 320 provides routing for the device substrate 310. The contact vias and conductive lines may include copper, titanium nitride, or a combination thereof. OS-FeFETs 200, fabricated using method 100 in FIG. 1 and having either the first configuration shown in FIG. 14 or the second configuration shown in FIG. 18, may be disposed in the fifth to the eighth metal layers in the interconnect structure 320 from the device substrate 310. The IC die 300 in FIG. 21 includes OS-FeFETs 200 having the second configuration (shown in FIG. 18) but it should be understood that OS-FeFETs 200 having the first configuration (shown in FIG. 14) may be similarly deployed in the IC die 300. Given the complexity and density of the transistors 304 in the device substrate 310, the first four metal layers may be heavily packed with metal lines and contact vias required to interconnect the transistors 304. While it is possible to fabricate the OS-FeFETs 200 in the nineth metal layer or metal layers over the nineth metal layer, such OS-FeFETs 200 would be too far away from the transistors 304. The greater distances are compensated by additional wiring and the additional wiring may result in further parasitic capacitance or resistance. The OS-FeFETs 200 have greater feature dimensions such that they can be fabricated using ArF excimer laser having a wavelength at 193 nm. In some embodiments, a spacing S between two adjacent second source/drain contacts 242 may be between about 40 nm and about 100 nm. The spacing S is a lot greater than the gate pitch P of the FEOL transistors 304.

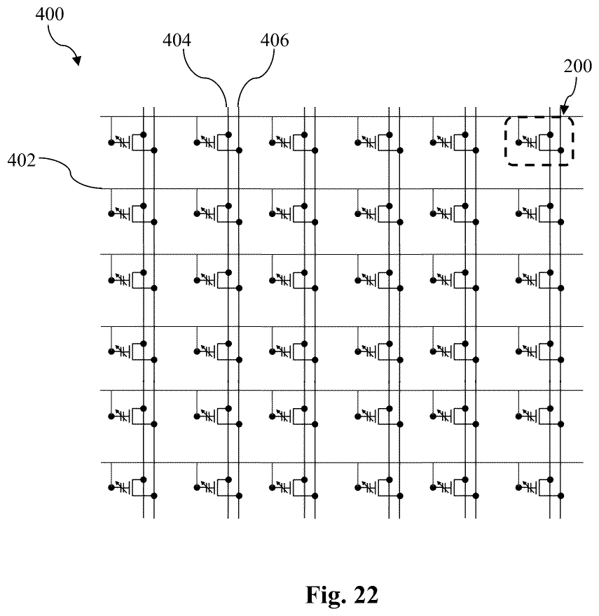

FIG. 22 illustrates an example memory array 400 implemented using the OS-FeFETs 200 fabricated using method 100 in FIG. 1. The OS-FeFETs 200 in the memory array 400 may have the first configuration shown in FIG. 14 or the second configuration shown in FIG. 18. In the memory array 400 shown in FIG. 22, gate electrodes of the OS-FeFETs 200 in a row are electrically coupled to a word line (WL) 402. Source/drain contacts of the OS-FeFETs 200 in a column are coupled to a bit line (BL) 404 or a select line (SL) 406. The bit line 404 and the select line 406 extend in parallel along a direction perpendicular to the word line 402.

The present disclosure provides for many different embodiments. In one embodiment, a semiconductor device is provided. The semiconductor device includes an electrode in a first dielectric layer, a ferroelectric layer over the electrode and the first dielectric layer, a high-k dielectric layer over the ferroelectric layer, an oxide semiconductor layer over the high-k dielectric layer, a second dielectric layer over the oxide semiconductor layer and the high-k dielectric layer, and a first contact feature and a second contact feature extending through the second dielectric layer to contact the oxide semiconductor layer.

In some embodiments, the electrode includes a barrier layer in contact with the first dielectric layer, and a metal fill layer over the barrier layer and spaced apart from the first dielectric layer by the barrier layer. In some embodiments, the barrier layer includes titanium nitride and the metal fill layer includes tungsten. In some instances, the ferroelectric layer includes hafnium zirconium oxide (HfZrO), hafnium aluminum oxide (HfAlO), hafnium lanthanum oxide (HfLaO), hafnium cerium oxide (HfCeO), hafnium oxide (HfO), hafnium gadolinium oxide (HfGdO), or hafnium silicate (HfSiO). In some implementations, the high-k dielectric layer includes aluminum oxide (AlO), titanium oxide (titanium oxide), niobium oxide (NbO), or lanthanum oxide (La₂O₃). In some embodiments, the oxide semiconductor layer includes zinc oxide, indium tungsten oxide, indium gallium zinc oxide, indium zinc oxide, or indium tin oxide. In some instances, the ferroelectric layer includes a first thickness and the high-k dielectric layer includes a second thickness smaller than the first thickness. In some embodiments, the oxide semiconductor layer includes a third thickness greater than the second thickness. In some embodiments, the second dielectric layer contacts the oxide semiconductor layer and the high-k dielectric layer.

In another embodiment, a device structure is provided. The device structure includes a metal layer, a ferroelectric layer disposed on the metal layer, a high-k dielectric layer disposed over the ferroelectric layer, a first contact feature and a second contact feature disposed on the high-k dielectric layer, and an oxide semiconductor layer disposed over the high-k dielectric layer and extending between the first contact feature and the second contact feature.

In some embodiments, the ferroelectric layer includes hafnium zirconium oxide (HfZrO), hafnium aluminum oxide (HfAlO), hafnium lanthanum oxide (HfLaO), hafnium cerium oxide (HfCeO), hafnium oxide (HfO), hafnium gadolinium oxide (HfGdO), or hafnium silicate (HfSiO). In some embodiments, the high-k dielectric layer includes aluminum oxide (AlO), titanium oxide (titanium oxide), niobium oxide (NbO), or lanthanum oxide (La₂O₃). In some embodiments, the oxide semiconductor layer includes zinc oxide, indium tungsten oxide, indium gallium zinc oxide, indium zinc oxide, or indium tin oxide. In some embodiments, each of the first contact feature and the second contact feature includes a barrier layer in contact with the oxide semiconductor layer, the high-k dielectric layer, and the ferroelectric layer and a metal fill layer over the barrier layer. The metal fill layer is spaced apart from the oxide semiconductor layer, the high-k dielectric layer, and the ferroelectric layer and the metal fill layer by the barrier layer. In some embodiments, the barrier layer includes titanium nitride and the metal fill layer includes tungsten.

In yet another embodiment, a method is provided. The method includes depositing a second dielectric layer over a first dielectric layer, forming an opening through the second dielectric layer, forming an electrode in the opening, depositing a ferroelectric layer over the electrode and the second dielectric layer, depositing a high-k dielectric layer over the ferroelectric layer, depositing an oxide semiconductor layer over the high-k dielectric layer, patterning the oxide semiconductor layer to expose a portion of the high-k dielectric layer, and forming a first contact feature and a second contact feature over the oxide semiconductor layer.

In some embodiments, the ferroelectric layer includes hafnium zirconium oxide (HfZrO), hafnium aluminum oxide (HfAlO), hafnium lanthanum oxide (HfLaO), hafnium cerium oxide (HfCeO), hafnium oxide (HfO), hafnium gadolinium oxide (HfGdO), or hafnium silicate (HfSiO). In some embodiments, the high-k dielectric layer includes aluminum oxide (AlO), titanium oxide (titanium oxide), niobium oxide (NbO), or lanthanum oxide (La₂O₃). In some embodiments, the oxide semiconductor layer includes zinc oxide, indium tungsten oxide, indium gallium zinc oxide, indium zinc oxide, or indium tin oxide. In some instances, the patterning of the oxide semiconductor layer includes depositing a mask layer over the oxide semiconductor layer, patterning the mask layer, and etching the oxide semiconductor layer using the mask layer as an etch mask.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
depositing a second dielectric layer over a first dielectric layer;
forming an opening through the second dielectric layer;
forming an electrode in the opening;
depositing a ferroelectric layer over the electrode and the second dielectric layer;
depositing a cap layer over the ferroelectric layer;
after the depositing of the cap layer, annealing the ferroelectric layer;
after the annealing, removing the cap layer;
depositing a high-k dielectric layer over the ferroelectric layer;
depositing an oxide semiconductor layer over the high-k dielectric layer;
patterning the oxide semiconductor layer to expose the high-k dielectric layer;
depositing a third dielectric layer over the patterned oxide semiconductor layer;
forming a first opening and a second opening through the third dielectric layer and the high-k dielectric layer such that the patterned oxide semiconductor layer is exposed in the first opening and the second opening; and
forming a first contact in the first opening and a second contact in the second opening.

2. The method of claim 1,
wherein the first dielectric layer comprises silicon oxide, silicon nitride, silicon oxynitride, fluorine-doped silicate glass (FSG), a low-k dielectric, or a combination thereof,
wherein the second dielectric layer comprises aluminum nitride, aluminum oxide, boron nitride, silicon oxynitride, silicon oxycarbonitride, or a combination thereof.

3. The method of claim 1, wherein the ferroelectric layer comprises hafnium zirconium oxide (HfZrO), hafnium aluminum oxide (HfAlO), hafnium lanthanum oxide (HfLaO), hafnium cerium oxide (HfCeO), hafnium gadolinium oxide (HfGdO), or hafnium silicate (HfSiO).

4. The method of claim 1, wherein the cap layer comprises titanium nitride.

5. The method of claim 1, wherein the annealing comprises a temperature between about 350° C. and about 400° C.

6. The method of claim 1, wherein the high-k dielectric layer comprises aluminum oxide (Al₂O₃), titanium oxide (TiO₂), niobium oxide (NbO), or lanthanum oxide (La₂O₃).

7. The method of claim 1, wherein the first opening and the second opening vertically overlap the electrode.

8. The method of claim 1, wherein the electrode, the first contact and the second contact comprise tungsten (W), ruthenium (Ru), or molybdenum (Mo).

9. The method of claim 1, wherein a thickness of high-k dielectric layer is smaller than a thickness of the ferroelectric layer or a thickness of the oxide semiconductor layer.

10. The method of claim 1, wherein the first opening and the second opening do not extend through the ferroelectric layer.

11. A method, comprising:
depositing a second dielectric layer over a first dielectric layer;
forming an opening through the second dielectric layer;
forming an electrode in the opening;
depositing a ferroelectric layer over the electrode and the second dielectric layer;
treating the ferroelectric layer to promote formation of a ferroelectric orthorhombic phase in the ferroelectric layer;
depositing a high-k dielectric layer over the treated ferroelectric layer;
depositing an oxide semiconductor layer over the high-k dielectric layer;
patterning the oxide semiconductor layer to expose the high-k dielectric layer;
depositing a third dielectric layer over the patterned oxide semiconductor layer;
forming a first opening and a second opening through the third dielectric layer and the high-k dielectric layer such that the patterned oxide semiconductor layer is exposed in the first opening and the second opening; and
forming a first contact in the first opening and a second contact in the second opening.

12. The method of claim 11, wherein the treating comprises:
depositing a cap layer over the ferroelectric layer;
after the depositing of the cap layer, annealing the ferroelectric layer; and
after the annealing, removing the cap layer.

13. The method of claim 12, wherein the cap layer comprises titanium nitride.

14. The method of claim 12, wherein the annealing comprises a temperature between about 350° C. and about 400° C.

15. The method of claim 11, wherein the ferroelectric layer comprises hafnium zirconium oxide (HfZrO), hafnium aluminum oxide (HfAlO), hafnium lanthanum oxide (HfLaO), hafnium cerium oxide (HfCeO), hafnium gadolinium oxide (HfGdO), or hafnium silicate (HfSiO).

16. The method of claim 11, wherein, after the forming of the first contact and the second contact, the first contact and the second contact interfaces sidewalls of the oxide semiconductor layer and the high-k dielectric layer.

17. A method, comprising:
depositing a second dielectric layer over a first dielectric layer;
forming an opening through the second dielectric layer;
forming an electrode in the opening;
depositing a ferroelectric layer over the electrode and the second dielectric layer;
treating the ferroelectric layer to promote formation of a ferroelectric orthorhombic phase in the ferroelectric layer;
depositing a high-k dielectric layer over the treated ferroelectric layer;
depositing an oxide semiconductor layer over the high-k dielectric layer;
patterning the oxide semiconductor layer to expose the high-k dielectric layer;
depositing a third dielectric layer over the patterned oxide semiconductor layer;
forming a first opening and a second opening through the third dielectric layer and the high-k dielectric layer such that the patterned oxide semiconductor layer is exposed in the first opening and the second opening;
depositing a barrier layer over the first opening and the second opening to interface the ferroelectric layer, the high-k dielectric layer, the oxide semiconductor layer, and the third dielectric layer;
depositing a metal fill over the barrier layer; and
performing a planarization process to the barrier layer, the metal fill, and the third dielectric layer to form a first contact in the first opening and a second contact in the second opening.

18. The method of claim 17, wherein the treating comprises:
depositing a cap layer over the ferroelectric layer;
after the depositing of the cap layer, annealing the ferroelectric layer; and
after the annealing, removing the cap layer.

19. The method of claim 18, wherein the cap layer comprises titanium nitride.

20. The method of claim 18, wherein the annealing comprises a temperature between about 350° C. and about 400° C.
